(19) United States
(12) Patent Application Publication
(10) Pub. No.: US 2026/0013094 A1
(43) Pub. Date: Jan. 8, 2026

(54) FRONTSIDE METAL TRACK REDUCTION

(71) Applicant: Taiwan Semiconductor Manufacturing Company, Ltd., Hsinchu (TW)

(72) Inventors: Yung-Ting Chang, New Taipei City (TW); Jui-Lin Chen, Taipei City (TW)

(21) Appl. No.: 18/918,264

(22) Filed: Oct. 17, 2024

Related U.S. Application Data
(60) Provisional application No. 63/667,271, filed on Jul. 3, 2024.

(51) Int. Cl. H10B 10/00; H01L 27/092; H01L 29/06; H01L 29/417

(52) U.S. Cl. CPC H10B 10/12; H10D 62/116; H10D 64/251; H10D 84/856

(57) ABSTRACT

A semiconductor structure according to the present disclosure includes a backside metal line, a backside dielectric layer over the backside metal line, a first source/drain feature and a second source/drain feature over the backside dielectric layer, a first backside contact extending through the backside dielectric layer to couple to a bottom surface of the first source/drain feature, a second backside contact extending through the backside dielectric layer to couple to a bottom surface of the second source/drain feature, a dielectric layer disposed over the backside dielectric layer, the first source/drain feature and the second source/drain feature, a common contact extending through the dielectric layer to electrically couple to the first source/drain feature and the second source/drain feature, an etch stop layer disposed over and interfacing the dielectric layer and the common contact. The common contact is not electrically coupled to any conductive feature that extends through the etch stop layer.

### PRIORITY DATA

This application claims priority to U.S. Provisional Patent Application Ser. No. 63/667,271, filed Jul. 3, 2024, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Static random-access memory (“SRAM”) generally refers to any memory or storage that can retain stored data only when power is applied. As integrated circuit (IC) technologies progress towards smaller technology nodes, multi-gate structures, such as fin-like field effect transistors (FinFETs) or gate-all-around (GAA) transistors, are integrated into SRAM cells to enhance performance. As dimensions of SRAM cells continue to shrink, the contact structures that functionally interconnect the transistors in SRAM cells present additional challenges in reduction of resistance (R) and capacitance (C).

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit schematic of an SRAM cell according to various aspects of the present disclosure.

FIG. 2 is a top view of an SRAM cell, according to various aspects of the present disclosure.

FIG. 3 is a fragmentary top view of a frontside interconnect structure of an SRAM quad-cell, according to various aspects of the present disclosure.

FIG. 4 is fragmentary cross-sectional view along cross section A-A′ in FIG. 3, according to various aspects of the present disclosure.

FIG. 5 is fragmentary cross-sectional view along cross section B-B′ in FIG. 3, according to various aspects of the present disclosure.

FIG. 6 is a fragmentary top view of a source/drain contact structure (MD/VD) of an SRAM quad-cell in FIG. 3, according to various aspects of the present disclosure.

FIG. 7 is a fragmentary top view of a first metal layer (M0) of an SRAM quad-cell in FIG. 3, according to various aspects of the present disclosure.

FIG. 8 is a fragmentary top view of a second metal layer (M1) of an SRAM quad-cell in FIG. 3, according to various aspects of the present disclosure.

FIG. 9 is a fragmentary top view of a third metal layer (M2) of an SRAM quad-cell in FIG. 3, according to various aspects of the present disclosure.

FIG. 10 is a fragmentary top view of a fourth metal layer (M3) of an SRAM quad-cell in FIG. 3, according to various aspects of the present disclosure.

FIG. 11 is fragmentary cross-sectional view along cross section A-A′ in FIG. 3, according to a first embodiment of the present disclosure.

FIG. 12 is fragmentary cross-sectional view along cross section B-B′ in FIG. 3, according to a first embodiment of the present disclosure.

FIG. 13 is a fragmentary top view of a source/drain structure (MD/VD) of an SRAM quad-cell in FIG. 3, according to a first embodiment of the present disclosure.

FIG. 14 is a fragmentary top view of a first metal layer (M0) of an SRAM quad-cell in FIG. 3, according to a first embodiment of the present disclosure.

FIG. 15 is a fragmentary top view of a second metal layer (M1) of an SRAM quad-cell in FIG. 3, according to a first embodiment of the present disclosure.

FIG. 16 is a fragmentary top view of a third metal layer (M2) of an SRAM quad-cell in FIG. 3, according to a first embodiment of the present disclosure.

FIG. 17 is a fragmentary top view of a fourth metal layer (M3) of an SRAM quad-cell in FIG. 3, according to a first embodiment of the present disclosure.

FIG. 18 is fragmentary cross-sectional view along cross section A-A′ in FIG. 3, according to a second embodiment of the present disclosure.

FIG. 19 is fragmentary cross-sectional view along cross section B-B′ in FIG. 3, according to a second embodiment of the present disclosure.

FIG. 20 is a fragmentary top view of a source/drain structure (MD/VD) of an SRAM quad-cell in FIG. 3, according to a second embodiment of the present disclosure.

FIG. 21 is fragmentary cross-sectional view along cross section A-A′ in FIG. 3, according to a third embodiment of the present disclosure.

FIG. 22 is fragmentary cross-sectional view along cross section B-B′ in FIG. 3, according to a third embodiment of the present disclosure.

FIG. 23 is a fragmentary top view of a first metal layer (M0) of an SRAM quad-cell in FIG. 3, according to a third embodiment of the present disclosure.

FIG. 24 is fragmentary cross-sectional view along cross section A-A′ in FIG. 3, according to a fourth embodiment of the present disclosure.

FIG. 25 is fragmentary cross-sectional view along cross section B-B′ in FIG. 3, according to a fourth embodiment of the present disclosure.

FIG. 26 is a fragmentary top view of a second metal layer (M1) of an SRAM quad-cell in FIG. 3, according to a fourth embodiment of the present disclosure.

FIG. 27 is fragmentary cross-sectional view along cross section A-A′ in FIG. 3, according to a fifth embodiment of the present disclosure.

FIG. 28 is fragmentary cross-sectional view along cross section B-B′ in FIG. 3, according to a fifth embodiment of the present disclosure.

FIG. 29 is a fragmentary top view of a third metal layer (M2) of an SRAM quad-cell in FIG. 3, according to a fifth embodiment of the present disclosure.

FIG. 30 is fragmentary cross-sectional view along cross section A-A′ in FIG. 3, according to a sixth embodiment of the present disclosure.

FIG. 31 is fragmentary cross-sectional view along cross section B-B′ in FIG. 3, according to a sixth embodiment of the present disclosure.

FIG. 32 is a fragmentary top view of a fourth metal layer (M3) of an SRAM quad-cell in FIG. 3, according to a sixth embodiment of the present disclosure.

FIG. 33 is fragmentary cross-sectional view along cross section A-A′ in FIG. 3, according to a seventh embodiment of the present disclosure.

FIG. 34 is fragmentary cross-sectional view along cross section B-B′ in FIG. 3, according to an eighth embodiment of the present disclosure.

FIG. 35 is a fragmentary top view of a source/drain structure (MD/VD) of an SRAM quad-cell in FIG. 3, according to an eighth embodiment of the present disclosure.

FIG. 36 is a fragmentary top view of a first metal layer (M0) of an SRAM quad-cell in FIG. 3, according to an eighth embodiment of the present disclosure.

FIG. 37 is a fragmentary top view of a second metal layer (M1) of an SRAM quad-cell in FIG. 3, according to an eighth embodiment of the present disclosure.

FIG. 38 is a fragmentary top view of a third metal layer (M2) of an SRAM quad-cell in FIG. 3, according to an eighth embodiment of the present disclosure.

FIG. 39 is a fragmentary top view of a fourth metal layer (M3) of an SRAM quad-cell in FIG. 3, according to an eighth embodiment of the present disclosure.

FIG. 40 is fragmentary cross-sectional view along cross section A-A′ in FIG. 3, according to a ninth embodiment of the present disclosure.

FIG. 41 is fragmentary cross-sectional view along cross section B-B′ in FIG. 3, according to a ninth embodiment of the present disclosure.

FIG. 42 is fragmentary cross-sectional view along cross section A-A′ in FIG. 3, according to a tenth embodiment of the present disclosure.

FIG. 43 is fragmentary cross-sectional view along cross section B-B′ in FIG. 3, according to a tenth embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data in a static form as long as the memory has power. Compared to dynamic RAM (DRAM), SRAM is faster and more reliable and does not need to be refreshed. SRAM is widely used in many applications, such as a computer's cache memory and as part of the random-access memory of digital-to-analog converter on a video card. As integrated circuit (IC) technologies progress towards smaller technology nodes, multi-gate structures, such as fin-like field effect transistors (FinFETs) or gate-all-around (GAA) transistors, are integrated into SRAM cells to enhance performance. The shrinkage in dimensions presents stress on electrical routing. When only a frontside interconnect structure is present, contact via and metal lines are tightly spaced and the frontside connections to various transistor nodes in an SRAM cell may exhibit high resistance. The tight spacing and the high contact resistance may lead to high resistance and capacitance, which may lead to low drive current and slow speed.

The present disclosure provides SRAM devices that include not only a frontside interconnect but also a backside interconnect to improve performance of SRAM devices. In one embodiment, sources of pull-down transistors are coupled to a backside ground rail by way of backside contacts to improve pull-down current while sources of pass-gate transistors are not coupled to the backside ground rail. In order to reduce resistance and capacitance of the frontside contact structures, some or all of the frontside contact structures that would be electrically coupled to the sources of the pull-down transistors may be omitted. In one embodiment, while a common source contact is formed to couple to the sources of the pull-down transistors, no conductive feature is formed to physically contact a top surface of the common source contact. The omission of frontside contact structures may allow wider metal lines or greater spacing between metal lines.

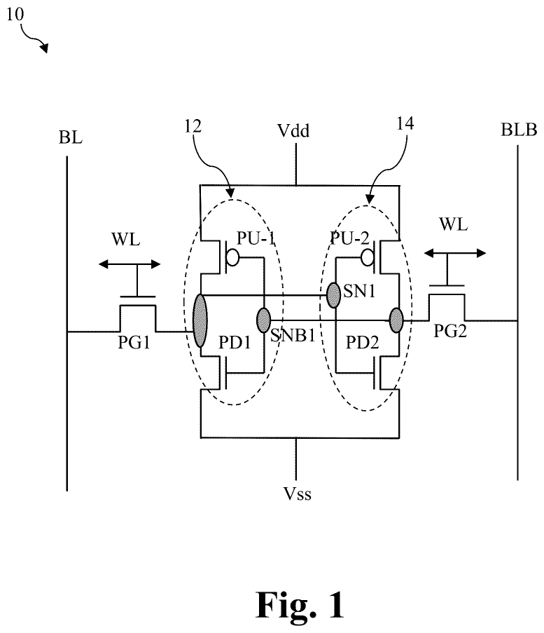

FIG. 1 illustrates an example type of memory device in which transistors such as planar transistors, FinFET transistors, or gate-all-around (GAA) transistors may be implemented. Embodiments describe in the present disclosure include GAA transistors. In that regard, FIG. 1 illustrates the circuit schematic of an example SRAM device, for example, as a single-port SRAM cell (e.g., 1-bit SRAM cell) 10. The single-port SRAM cell 10 includes first and second pass-gate transistors PG1 and PG2, first and second pull-up transistors PU1 and PU2, and first and second pull-down transistors PD1 and PD2. The gates of the first and second pass-gate transistors PG1 and PG2 are electrically coupled to word-line (WL) that determines whether the SRAM cell 10 is selected or not. In the SRAM cell 10, a memory bit (e.g., a latch or a flip-flop) is formed of the first and second pull-up transistors PU1 and PU2 and the first and second pull-down transistors PD1 and PD2 to store a bit of data. The complementary values of the bit are stored in a first storage node SN1 and a first complementary storage node SNB1. The stored bit can be written into, or read from, the SRAM cell 10 through Bit-line (BL) and Bit-Line Bar (BLB). In this arrangement, the BL and BLB may carry complementary bit-line signals. The SRAM cell 10 is powered through a positive power supply voltage Vdd and is also connected to a ground potential Vss.

The SRAM cell 10 includes a first inverter 12 formed of the first pull-up transistor PU1 and the first pull-down transistor PD1 as well as a second inverter 14 formed of the second pull-up transistor PU2 and the second pull-down transistor PD2. As shown in FIG. 1, drains of the first pull-up transistor PU1 and the first pull-down transistor PD1 are coupled together and drains of the second pull-up transistor PU2 and the second pull-down transistor PD2 are coupled together. The first inverter 12 and the second inverter 14 are coupled between the positive supply voltage Vdd and the ground potential Vss. As shown in FIG. 1, the first inverter 12 and the second inverter 14 are cross coupled. That is, the first inverter 12 has an input coupled to the output of the second inverter 14. Likewise, the second inverter 14 has an input coupled to the output of the first inverter 12. The output of the first inverter 12 is referred to as the first storage node SN1. Likewise, the output of the second inverter 14 is referred to as the first complementary storage node SNB1. In a normal operating mode, the first storage node SN1 is in the opposite logic state (logic high or logic low) as the first complementary storage node SNB1. By employing the two cross-coupled inverters, the SRAM cell 10 can hold the data using a latched structure so that the stored data will not be lost without applying a refresh cycle as long as power is supplied through Vdd.

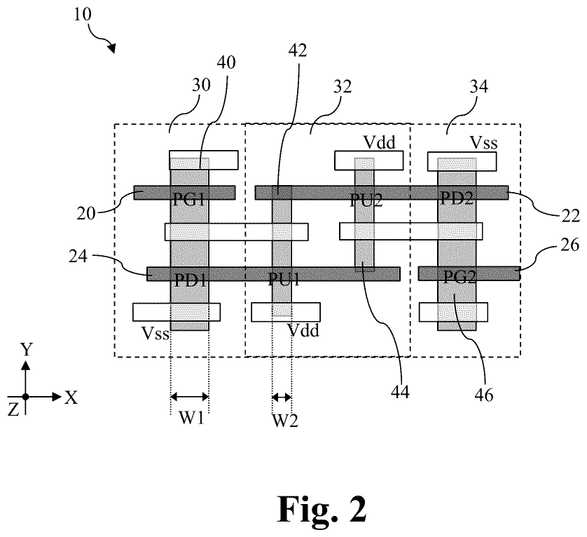

Referring now to FIG. 2, shown therein is an example layout of the SRAM cell 10 in FIG. 1. Like the SRAM cell 10 in FIG. 1, the layout in FIG. 2 includes six (6) transistors functioning as the first pass-gate transistor PG1, the second pass-gate transistor PG2, the first pull-up transistor PU1, the second pull-up transistor PU2, the first pull-down transistor PD1, and the second pull down transistor PD2. In some implementations represented in FIG. 2, the SRAM cell 10 may be formed over an n-type well 32 (or N well 32) sandwiched between two p-type wells 30 and 34 (or P wells 30 and 34). The N well 32 and P wells 30, 34 are formed over a substrate by ion implantation processes. In some embodiments, as shown in FIG. 2, the first pass-gate transistor PG1, the first pull-down transistor PD1, the second pull-down transistor PD2, and the second pass-gate transistor PG2 may be formed over the P wells 30 and 34; and the first pull-up transistor PU1 and the second pull-up transistor PU2 are formed in the N well 32. In these embodiments, the first pass-gate transistor PG1, the first pull-down transistor PD1, the second pull-down transistor PD2, and the second pass-gate transistor PG2 are n-type GAA transistors; and the first pull-up transistor PU1 and the second pull-up transistor PU2 are p-type GAA transistors.

In some embodiments, the SRAM cell 10 includes four fin-shaped vertical stacks-a first fin-shaped vertical stack 40, a second fin-shaped vertical stack 42, a third fin-shaped vertical stack 44, and a fourth fin-shaped vertical stack 46. The first fin-shaped vertical stack 40 is formed over the P well 30 and forms the channel regions of the first pass-gate transistor PG1 and the first pull-down transistor PD1. The second fin-shaped vertical stack 42 and third fin-shaped vertical stack 44 are formed over the N well 32 and form the channel regions of the first pull-up transistor PU1 and the second pull-up transistor PU2, respectively. The fourth fin-shaped vertical stack 46 is formed over the P well 34 and forms the channel regions of the second pull-down transistor PD2 and the second pass-gate transistor PG2. Each of the first, second, third, and fourth fin-shaped vertical stacks 40, 42, 44, and 46 may include about two (2) to about ten (10) channel members. In some embodiments, each of the first, second, third, and fourth fin-shaped vertical stacks 40, 42, 44, and 46 includes 3 channel members. Each of the first, second, third, and fourth fin-shaped vertical stacks 40, 42, 44, and 46 may be referred to as an active region. For each of the GAA transistors described herein, channel members in a vertical stack extend between two source/drain features. Because the source/drain features are formed using epitaxial processes, such molecular beam epitaxy (MBE) or vapor phase epitaxy (VPE), they may also be referred to epitaxial features.

In some instances, the fin-shaped vertical stacks may be formed by depositing or epitaxially growing alternating layers of two different semiconductor materials, patterning the alternating layers to form fin-shaped structures, and selectively removing layers formed of one of the two semiconductor materials. For example, alternating layers of epitaxially grown silicon (Si) and silicon germanium (SiGe) can be formed on a substrate. The substrate may be a silicon (Si) substrate. The alternating layers may then be patterned to form fin-shaped structures that include stacks of interleaved Si strips and SiGe stripes. In processes to form a channel region of a transistor in a SRAM cell, the channel region of the fin-shaped structures may undergo different etching processes to selectively remove the SiGe strips, releasing silicon layers as suspended silicon channel members. The channel members may assume different shapes and dimensions and may be referred to as nanostructure, nanowires, or nanosheets. These fin-shaped structures are separated by an isolation feature, such as a shallow trench isolation (STI) feature. In some implementations, each of the fin-shaped vertical stacks may include a top portion formed from the alternating layers and a base portion formed from the substrate. The base portions of the fin-shaped vertical stacks have a shape of a fin and may be referred to as fin structures or base fins. The base portions of the fin-shaped vertical stacks may be substantially buried in the isolation feature and top ends of the base portions of the fin-shaped vertical stacks may be level with a top surface of the isolation feature. The top portions of the fin-shaped vertical stacks extend from and rise above the isolation feature.

Reference is still made to FIG. 2. The channel members in the first fin-shaped vertical stack 40 form channel regions of the first pass-gate transistor PG1 and the first pull-down transistor PD1. The channel members in the second fin-shaped vertical stack 42 form channel regions of the first pull-up transistor PU1. The channel members in the third fin-shaped vertical stack 44 form channel regions of the second pull-up transistor PU2. The channel members in the fourth fin-shaped vertical stack 46 form channel regions of the second pull-down transistor PD2 and the second pass-gate transistor PG2. In the depicted embodiments, the first fin-shaped vertical stack 40 and the fourth fin-shaped vertical stack 46 are used to form n-type GAA transistors and the second fin-shaped vertical stack 42 and the third fin-shaped vertical stack 44 are used to form p-type GAA transistors. In the embodiments illustrated in FIG. 2, the first pass-gate transistor PG1, the first pull-down transistor PD1, the second pass-gate transistor PG2, the second pull-down transistor PD2 are n-type GAA transistors, and the first pull-up transistor PU1 and the second pull-up transistor PU-2) are p-type GAA transistors. In FIG. 2, each of the first fin-shaped vertical stack 40 and fourth fin-shaped vertical stack 46 has a first width WI along the X direction and each of the second fin-shaped vertical stack 42 and the third fin-shaped vertical stack 44 has a second width W2 along the X direction. In some embodiments, in order to achieve better read/write performance, the n-type GAA transistors have greater channel widths than the p-type GAA transistors. That is, the first width W1 may be greater than the second width W2. In some instances, a ratio of the first width W1 to the second width W2 (W1/W2) is between about 1 and about 5, including between about 1.1 and about 3.0.

GAA transistors of the present disclosure may be formed using two process flows. In a first process flow, channel members are released after formation of source/drain features. In a second process flow, channel members are released before formation of source/drain features. The channel members, which may be formed of silicon, are released from interleaving sacrificial layers that are formed silicon germanium. Because the formation of source/drain features includes epitaxy processes that involve elevated temperature and the elevated temperature may promote intermixing of silicon germanium in the sacrificial layers and silicon in the channel members, the first process flow tends to result in more intermixing of silicon germanium into silicon and the second process tends to result in little or no intermixing. The intermixing at the interfaces between channel members and sacrificial layers may affect selective removal of the sacrificial layers when the channel members are released. In general, the first process flow may include less process steps than the second process flow but the second process flow may result in channel members with greater channel widths and shape uniformity. Embodiments of the present disclosure may be applicable to SRAM cells formed of GAA transistors formed using both process flows.

As illustrated in FIG. 2, a channel of the first pass-gate transistor PG1 is controlled by a gate structure 20, channels of the first pull-down transistor PD1 and the first pull-up transistor PU1 are controlled by a gate structure 24, channels of the second pull-down transistor PD2 and the second pull-up transistor PU2 are controlled by a gate structure 22, and a channel of the second pass-gate transistor PG2 is controlled by a gate structure 26. As the gate structures 20 and 22 are segmented from a single gate structure, they are aligned lengthwise along the X direction. As the gate structures 24 and 26 are segmented from a single gate structure, they are aligned lengthwise along the X direction. The first fin-shaped vertical stack 40, the second fin-shaped vertical stack 42, the third fin-shaped vertical stack 44, and the fourth fin-shaped vertical stack 46 extend lengthwise along the Y direction, perpendicular to the X direction. In circuit and physical design, the SRAM cell 10 shown in FIG. 2 may serve as a repeating unit in an SRAM array. For case of signal routing, adjacent SRAM cells 10 in an SRAM array may be mirror images of one another along their borders.

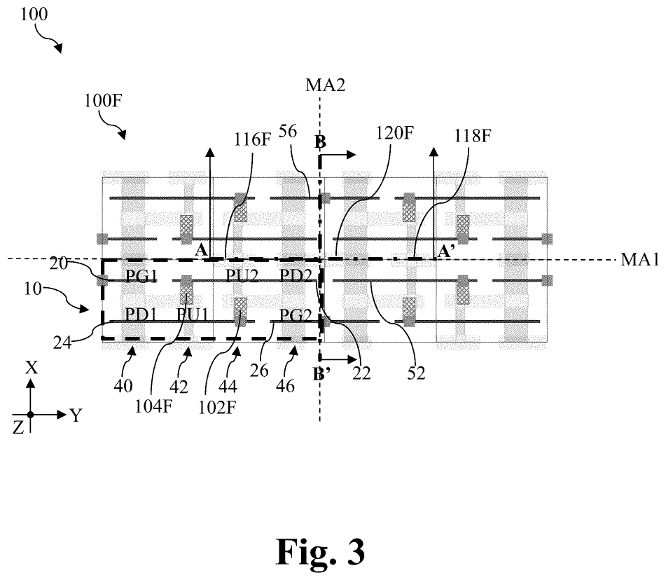

FIGS. 3-5 illustrate various aspects of an example embodiment where sources of two adjacent second pull-down transistor PD2 are electrically coupled to a backside ground rail by way of backside contacts. With respect to this example embodiment, FIG. 3 illustrates a frontside interconnect layer of an SRAM quad-cell 100 that includes 4 SRAM cells 10. An SRAM cell 10 is shown in FIG. 3 as a dotted rectangular box. For illustration purposes, FIG. 3 also includes a first mirror axis MA1, which extends along the Y direction and a second mirror axis MA2, which extends along the X direction. It can be seen that the SRAM cell across the first mirror axis MA1 from the SRAM cell 10 is a mirror image of the SRAM cell 10. Similarly, the SRAM cell across the second mirror axis MA2 from the SRAM cell is a mirror image of the SRAM cell 10. The mirror imaging configuration allows merging of the pull-up transistors, the pull-down transistors, and pass-gate transistors for efficient routing and electrical connection. The frontside interconnect layer in FIG. 3 includes butted contacts, such as a first frontside butted contact 102F and a second frontside butted contact 104F. The first frontside butted contact 102F couples a gate structure 24 of the first pull-up transistor PU1 to a source of the second pull-up transistor PU2. The second frontside butted contact 104F couples the gate structure 22 of the second pull-up transistor PU2 to the source of the first pull-up transistor PU1. FIG. 3 also shows a common frontside source contact 120F that couples together sources of two adjacent pull-down transistors.

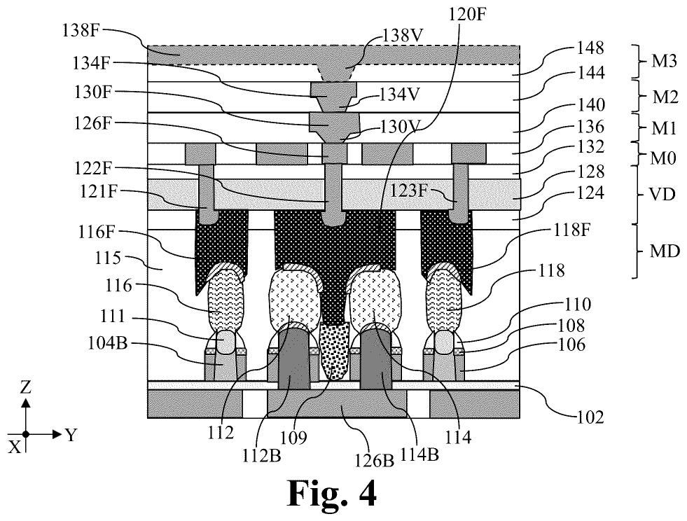

FIG. 4 illustrates a fragmentary cross-sectional view along cross section A-A′ in FIG. 3. As shown in FIG. 4, cross section A-A′ cuts through a source feature 116 of the second pull-up transistor PU2 and a source feature 112 of the second pull-down transistor PD2 of the SRAM cell 10 as well as a source feature 114 of the second pull-down transistor PD2 and a source feature 118 of the second pull-up transistor PU2 of a neighboring SRAM cell that is a mirror image of the SRAM cell 10 with respect to the second mirror axis MA2. The source feature 116 and the source feature 118 include silicon germanium (SiGe) doped with a p-type dopant, such as boron or boron difluoride (BF2). The source feature 112 and the source feature 114 include silicon (Si) doped with an n-type dopant, such as phosphorus (P) or arsenic (As). Because p-type source features 116 and 118 are formed from surfaces of narrower fin-shaped structures and n-type source features 112 and 114 are formed surfaces of wider fin-shaped structures, n-type source features 112 and 114 are wider along the Y direction than the p-type source features 116 and 118. The p-type source features 116 and 118 are disposed over base fins 104B, which are formed of a semiconductor material, such as silicon (Si). To control strain, a bottom isolation feature 109 is disposed between the base fin 104B and the p-type source feature 116 (or the p-type source feature 118). In some embodiments, the backside dielectric layer 102 may include silicon oxide and the bottom isolation feature 109 may include silicon nitride. A portion of a shallow trench isolation (STI) 106 is disposed along sidewalls of the base fin 104B and a gate spacer 110 is disposed along sidewalls of the bottom isolation feature 109. In some embodiments, a liner 108 is vertically sandwiched between the portion of the STI 106 and the gate spacer 110. In some embodiments, the STI 106 may include silicon oxide, the gate spacer 110 may include silicon oxycarbonitride or silicon carbonitride, and the liner 108 may include silicon nitride. The liner 108 functions to prevent loss of STI 106. In some embodiments, channel members of the GAA transistors in the SRAM cell are released by selectively removing a dummy layer that interleaves the channel members. Because the dummy layer and the STI 106 may be both formed of silicon oxide, the liner 108 is formed to cover the STI 106 to prevent damages to STI 106 during the channel release process.

Reference is still made to FIG. 4. A backside metal rail 126B is disposed below the backside dielectric layer 102. A first backside source contact 112B is formed to extend from a top surface of the backside metal rail 126B, through the backside dielectric layer 102 to electrically to a bottom surface of the n-type source feature 112. A second backside source contact 114B is formed to extend from the top surface of the backside metal rail 126B, through the backside dielectric layer 102 to electrically to a bottom surface of the n-type source feature 114. An isolation structure 111 is formed between the first backside source contact 112B and the second backside source contact 114B. The isolation structure 111 may include an inner layer and outer layer. In some instances, the inner layer may include silicon oxide and the outer layer may include silicon nitride, silicon oxycarbonitride, or silicon carbonitride. A dielectric constant of the outer layer is greater than a dielectric constant of the inner layer. As will be described further below, the isolation structure 111 functions to cut gate structures into segments and may also be referred to as a gate cut feature 111. In the example structure shown in FIG. 4, a first frontside source contact 116F is disposed over and electrically coupled to the p-type source feature 116, a second frontside source contact 118F is disposed over and electrically coupled to the p-type source feature 118, and a common frontside source contact 120F is disposed over and coupled to n-type source features 112 and 114. In some embodiments, the first frontside source contact 116F, the second frontside source contact 118F, and a common frontside source contact 12OF may include cobalt (Co), ruthenium (Ru), or tungsten (W). In one embodiment, they include tungsten (W). As shown in FIG. 4, the first frontside source contact 116F, the second frontside source contact 118F, and a common frontside source contact 120F are situated in a source/drain contact (MD) layer.

The source features 112, 114, 116, and 118 are disposed in the first interlayer dielectric (ILD) layer 115. A second ILD layer 124 is disposed over the first ILD layer 115. The first frontside source contact 116F, the second frontside source contact 118F, and the common frontside source contact 120F extend through the first ILD layer 115 and the second ILD layer 124 to couple to the source features 112, 114, 116, and 118. Top surfaces of the first frontside source contact 116F, the second frontside source contact 118F, and a common frontside source contact 120F are coplanar due to a planarization process. An etch stop layer (ESL) 128 is disposed on the coplanar top surfaces of the first frontside source contact 116F, the second frontside source contact 118F, the common frontside source contact 120F, and the second ILD layer 124. The ESL 128 may include silicon nitride, silicon carbide, silicon carbonitride, aluminum nitride, or aluminum oxynitride. A third ILD layer 132 is disposed on the ESL 128. A frontside contact via 122F extends through the third ILD layer 132 and the ESL 128 to electrically couple to the common frontside source contact 120F. A first contact via 121F extends through the third ILD layer 132 and the ESL 128 to electrically couple to the first frontside source contact 116F and a second contact via 123F extends through the third ILD layer 132 and the ESL 128 to electrically couple to the second frontside source contact 118F. The frontside contact via 122F, the first contact via 121F, and the second contact via 123F may include cobalt (Co), ruthenium (Ru), or tungsten (W) and is situated in a source/drain contact via (VD) layer. In one embodiment, they include tungsten (W). The common frontside source contact 120F is electrically coupled to a fourth metal layer (M3) metal rail 138F by way of the frontside contact via 122F, a first metal layer (M0) metal island 126F, a second metal layer (M1) metal island 130F, and a third metal layer (M2) metal line 134F. Referring to FIG. 4, the frontside connection to the n-type source features 112 and 114 includes contact structures situated in the MD layer, the VD layer, the M0 layer, the M1 layer, the M2 layer, and the M3 layer. When any of these contact structures is missing, the n-type source features 112 and 114 are not connected to the frontside power rail, which is the fourth metal layer (M3) metal rail 138F. Conversely, when any of these contact structures is missing, the n-type source features 112 and 114 are only connected to the backside metal rail 126B. The first metal layer (M0) is disposed in a first intermetal dielectric (IMD) layer 136, the second metal layer (M1) is disposed in a second IMD layer 140, the third metal layer (M2) is disposed in a third IMD layer 144, and the fourth metal layer (M3) is disposed in a fourth IMD layer 148. The first, second, third, and fourth IMD layers 136, 140, 144, and 148 may include silicon oxide. While not explicitly shown in the figures, the first, second, third, and fourth IMD layers 136, 140, 144, and 148 may be interleaved by etch stop layers that are formed of aluminum oxide, aluminum nitride, or aluminum oxynitride. In FIG. 4, the M3 metal rail 138F is shown in dotted lines because it is out of plane.

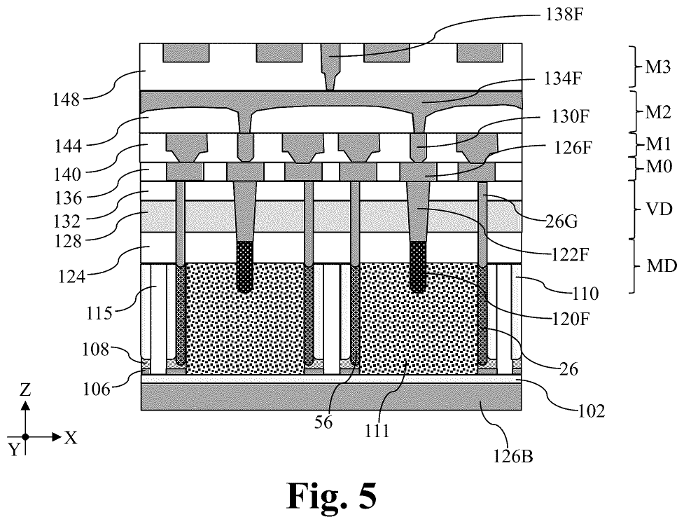

FIG. 5 illustrates a fragmentary cross-sectional view along cross section B-B′ in FIG. 3. The isolation structure 111 functions as a gate cut feature to divide gate structures. For example, as shown in FIG. 3, the gate structure 22 is aligned with another gate structure 52 in the mirror image SRAM cell on the other side of the second mirror axis MA2. The isolation structure 111 cuts between the gate structure 22 and the gate structure 52. Referring still to FIG. 3, the isolation structure 111 does not cut through gate structures 26 and 56, which are shown in FIG. 5 as being extending along sidewalls of the isolation structure 111. A gate contact 26G extends through the third ILD layer 132 and the ESL 128 to electrically couple to the gate structure 26. As shown in FIG. 5, a portion of the common frontside source contact 120F extends into the isolation structure 111. The STI 106 is covered and protected by the liner 108 to prevent damages to the STI 106. Cross-sectional views the backside metal rail 126B, the frontside contact via 122F, the first metal layer (M0) metal island 126F, the second metal layer (M1) metal island 130F, and the third metal layer (M2) metal line 134F, and the fourth metal layer (M3) metal rail 138F are shown in FIG. 5. Viewed in conjunction with FIG. 4, it can be seen that the backside metal rail 126B extends lengthwise along the X direction, the M2 metal line 134F extends lengthwise along the X direction, and the M3 metal rail 138F extends lengthwise along the Y direction. As shown in FIG. 5, the M3 metal rail 138F is not vertically aligned with the common frontside source contact 120F, the frontside contact via 122F, the first metal layer (M0) metal island 126F, and the second metal layer (M1) metal island 130F and that is why it is shown in dotted line in FIG. 4.

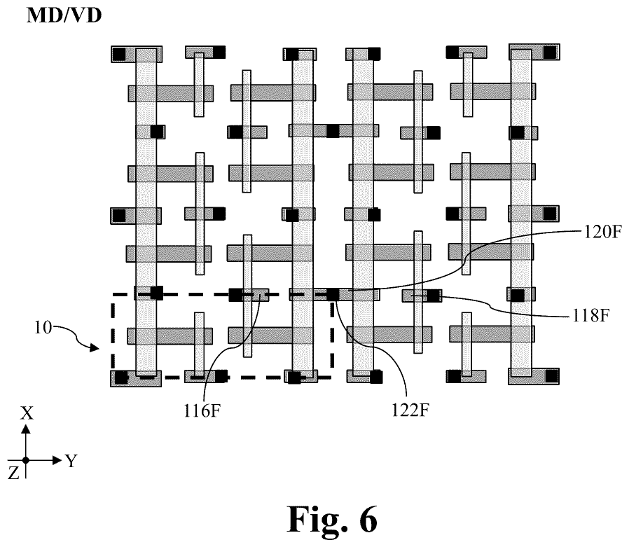

FIG. 6 is a fragmentary top view of source/drain contacts (MD) and source/drain contact vias (VD) of the SRAM quad-cell 100 in FIG. 3. FIG. 6 illustrates top views of the common frontside source contact 120F and the frontside contact via 122F. While the common frontside source contact 120F is longer than the first frontside source contact 116F and the second frontside source contact 118F along the Y direction, its existence does not necessarily impact the area of the first frontside source contact 116F and the second frontside source contact 118F. In other words, even when the common frontside source contact 120F is removed, the first frontside source contact 116F and the second frontside source contact 118F may not be enlarged much. This is so for at least two reasons. First, unless the benefits can be shared by all similarly situated source/drain contacts, enlarging only a few source/drain contact will only create process and performance inconsistency. Second, it is usually not advisable to extend a source/drain contact to overhang another source/drain feature because do so may increase the risk of electrical shorts.

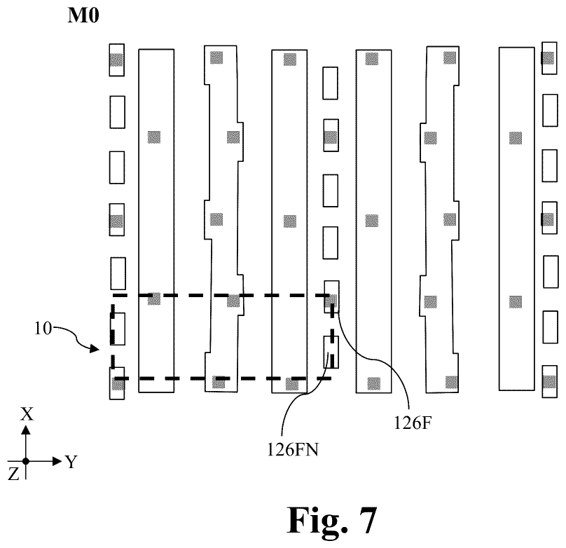

FIG. 7 is a fragmentary top view of the first metal layer (M0) of the SRAM quad-cell 100 in FIG. 3. As shown in FIG. 7, the M0 metal island 126F in the first metal layer (M0) is disposed directly over and physically and electrically contacts the frontside contact via 122F. Presence of the M0 metal island 126F compresses the space allowed for other similarly situated metal islands 126FN. In other words, when the M0 metal island 126F is removed, the metal islands 126FN can be at least lengthened along the X direction to increase process window and via landing area.

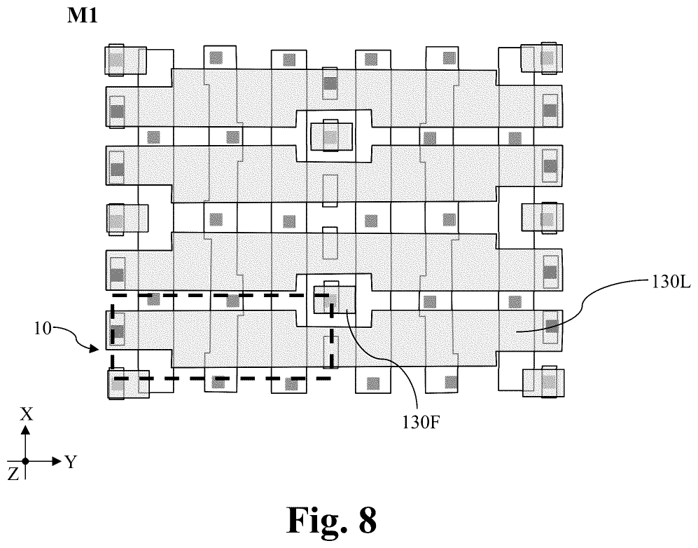

FIG. 8 is a fragmentary top view of the second metal layer (M1) of the SRAM quad-cell 100 in FIG. 3. As illustrated in FIG. 8, the M1 metal island 130F in the second metal layer (M1) is disposed directly over the M0 metal island 126F and includes a contact via 130V (shown in FIG. 4) to physically and electrically contacts the M0 metal island 126F. The inclusion of the M1 metal island 130F requires M1 metal line 130L to have carve-outs. In other words, when the M1 metal island 130F and similarly situated M1 metal islands are removed, the M1 metal line 130L may have a rectangular shape that is easier to form with greater process window.

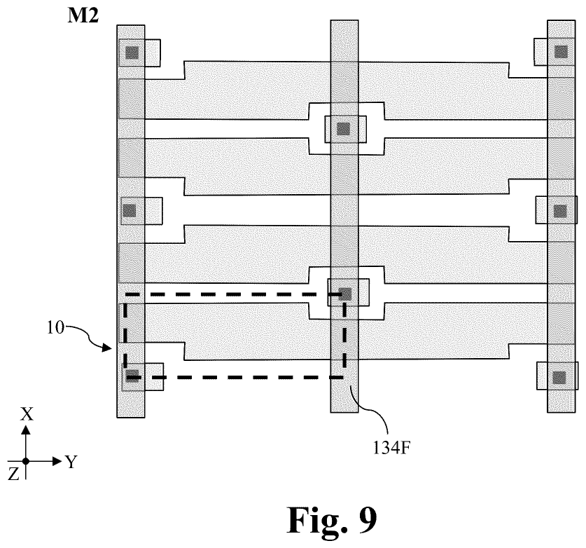

FIG. 9 is a fragmentary top view of the third metal layer (M2) of the SRAM quad-cell 100 in FIG. 3. In FIG. 9, the M2 metal line 134F extends lengthwise along the X direction and includes a contact via 134V to physically and electrically contact the M1 metal island 130F. The third metal layer (M2) over the SRAM quad-cell 100 only includes M2 metal line 134F. If all M2 metal lines 134F are removed, the entire third metal layer (M2) over the SRAM quad-cell 100 may be repurposed to include conductive features that improve performance of the SRAM quad-cell 100.

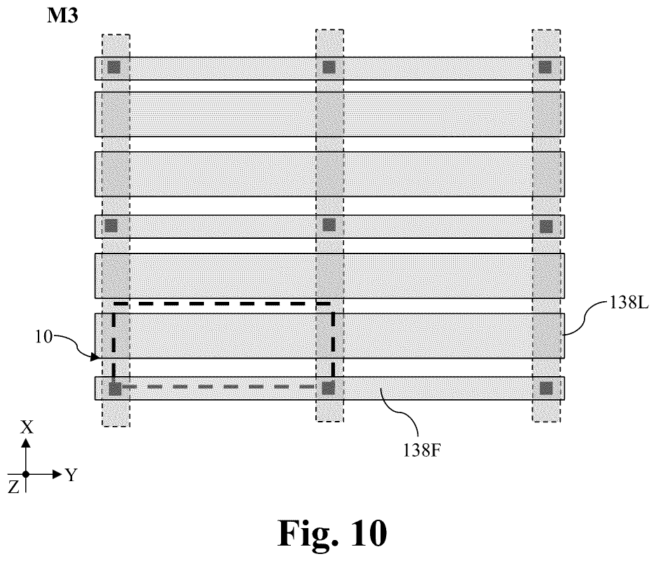

FIG. 10 is a fragmentary top view of the fourth metal layer (M3) of the SRAM quad-cell 100 in FIG. 3. As illustrated in FIG. 10, the M3 metal rail 138F extends lengthwise along the Y direction and includes a contact via 138V to physically and electrically couple to the M2 metal line 134F. The inclusion of the M3 metal rail 138F compresses area available for M3 metal lines 138L. In other words, when the M3 metal rail 138F is removed, the M3 metal lines 138L may each have a greater width to reduce resistance or be spaced apart from one another at a larger spacing to reduce parasitic capacitance.

As processes for forming GAA transistors improve over time, channel members in GAA transistors may have a more uniform shape and a smoother surface to exhibit a greater channel current and smaller channel resistance. In light of the reduced channel resistance, coupling sources of the pull-down transistors to the ground rail or a negative supply voltage through both a frontside contact and a backside contact may become redundant and unnecessary. This is especially true when the frontside connections in multiple metal layers take up space that can accommodate other conductive features. The present disclosure provides various embodiments where a portion or all of the connections to the frontside power rail are removed.

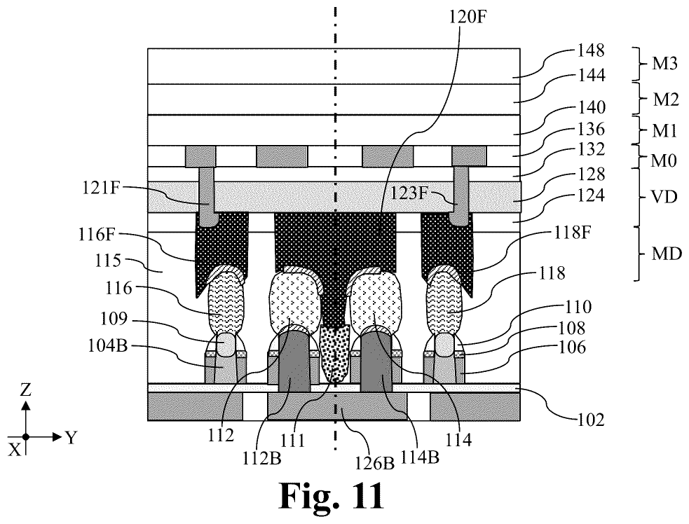

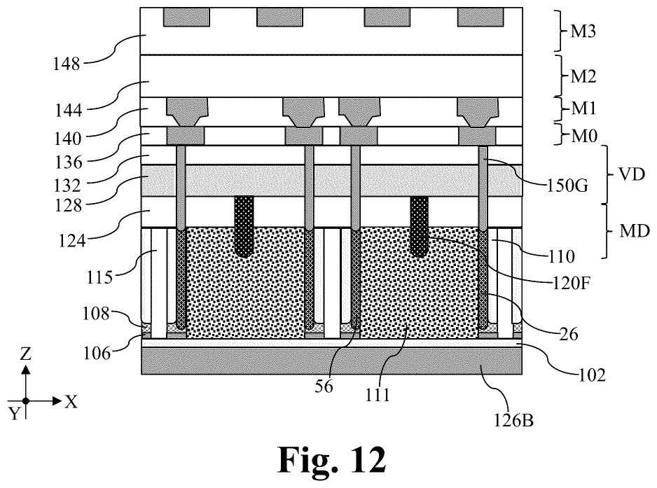

FIGS. 11-17 illustrate a first embodiment of the present disclosure. In the first embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. The common frontside source contact 120F extends through the first ILD layer 115 and the second ILD layer 124 to electrically couple to the source feature 112 of the second pull-down transistor PD2 of the SRAM cell 10 and the source feature 114 of the second pull-down transistor PD2 of a neighboring SRAM cell. As shown in FIG. 11, the common frontside source contact 120F spans over the source features 112 and 114 along the Y direction and interfaces them by way of a silicide feature, which may include tungsten silicide, titanium silicide, cobalt silicide, or nickel silicide. In some embodiments represented in FIG. 11, a lower portion of the common frontside source contact 120F is disposed between the source feature 112 and the source feature 114 and lands on the isolation structure 111. As shown in FIGS. 11 and 12, the ESL 128 is disposed directly on the top surfaces of the common frontside source contact 120F and the second ILD layer 124. In the first embodiment, the common frontside source contact 120F is not electrically coupled to any conductive features disposed thereover. That is, no conductive features extend through the ESL 128 to electrically or physically contact a top surface of the common frontside source contact 120F.

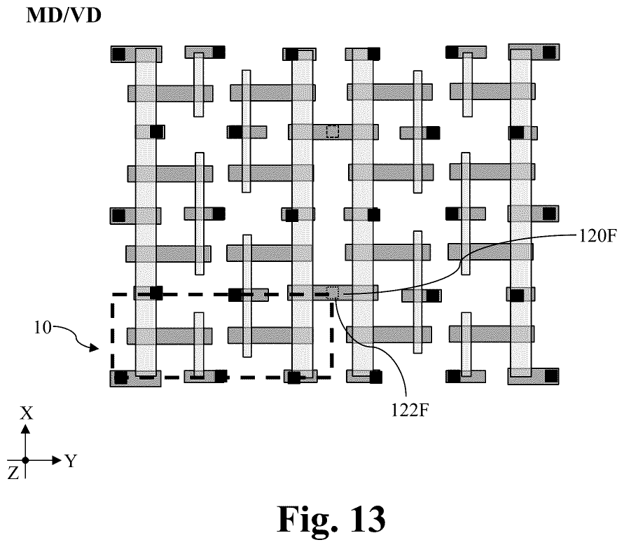

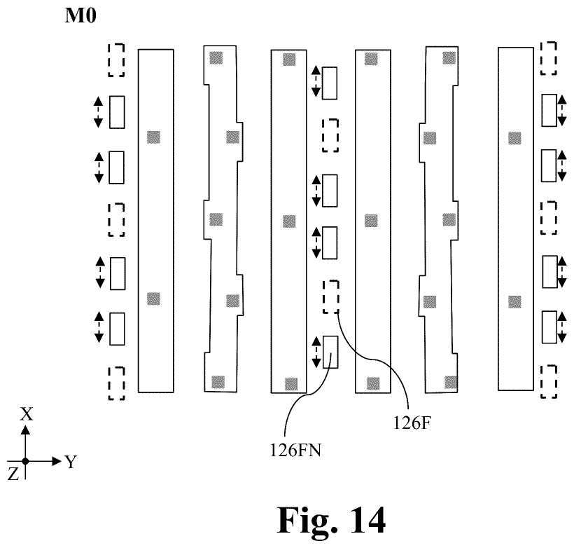

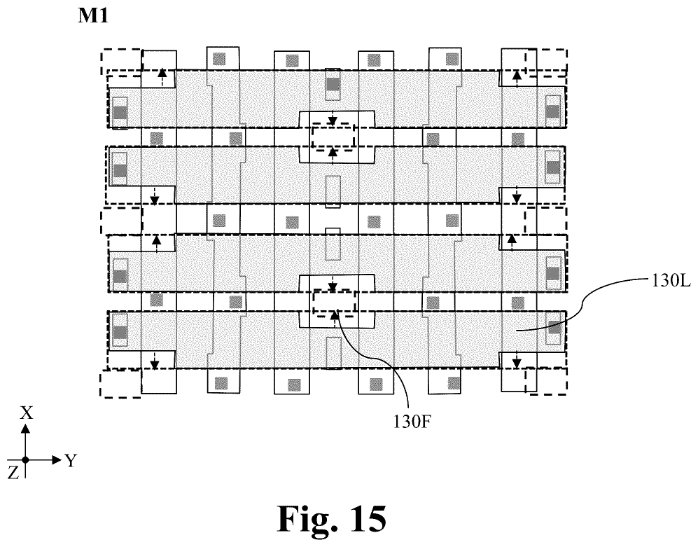

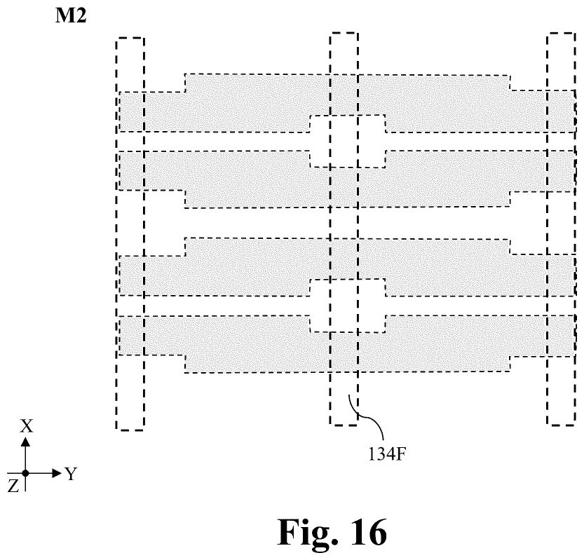

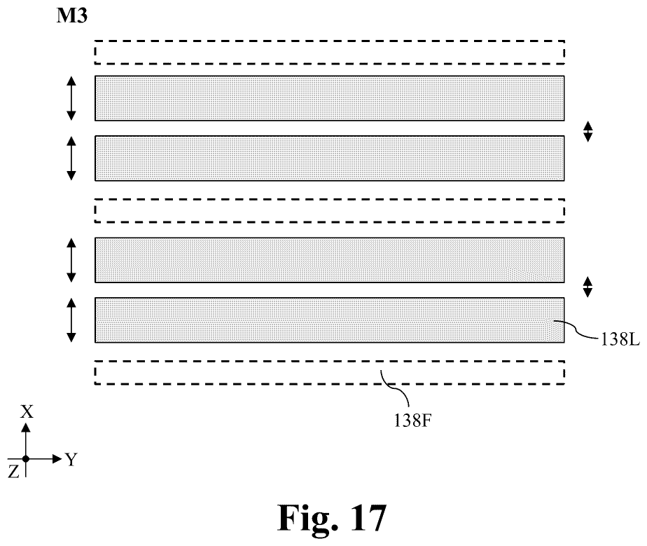

As shown in FIGS. 11-17, the frontside contact via 122F, the M0 metal island 126F, the M1 metal island 130F, the M2 metal line 134F, and the M3 metal rail 138F are all omitted. That is, not only the frontside power rail-the M3 metal rail 138F is removed, but all conductive features that are on the conduction path between the common frontside source contact 120F and the M3 metal rail 138F are omitted. Keeping the common frontside source contact 120F is not a trivial option. When the common frontside source contact 120F is still formed as in the first embodiment, all source/drain features in the SRAM cell 10 are subject to etching when the contact openings (such as the opening for the common frontside source contact 120F) are formed. If the common frontside source contact 120F is omitted, only the source features 112 and 114 are not etched, such inconsistent etching may introduce reliability issues. When the common frontside source contact 120F is kept, source features 112 and 114 are similarly etched as the other source/drain features in the SRAM cell, which may improve process window and performance of the memory device. Referring to FIG. 13, the common frontside source contact 120F is still present but the frontside contact via 122F is omitted. Referring to FIG. 14, the M0 metal island 126F is omitted from the first metal layer M0 such that the other similarly situated metal islands 126FN may be lengthened along the X direction or spacing among the other similarly situated metal islands 126FN may be enlarged. Referring to FIG. 15, the M1 metal island 130F is omitted from the second metal layer M1 such that the M1 metal lines 130L may be straightened for reduced resistance and improved process window. Referring to FIG. 16, the M2 metal lines 134F are omitted from the third metal layer M2 such that the third metal layer M2 over the SRAM cell 10 may be repurposed. Referring to FIG. 17, the m3 metal rails 138F are omitted from the fourth metal layer M3 such that the M3 metal lines 138L in the fourth metal layer M3 may be widened along the X direction and may be moved further apart from one another.

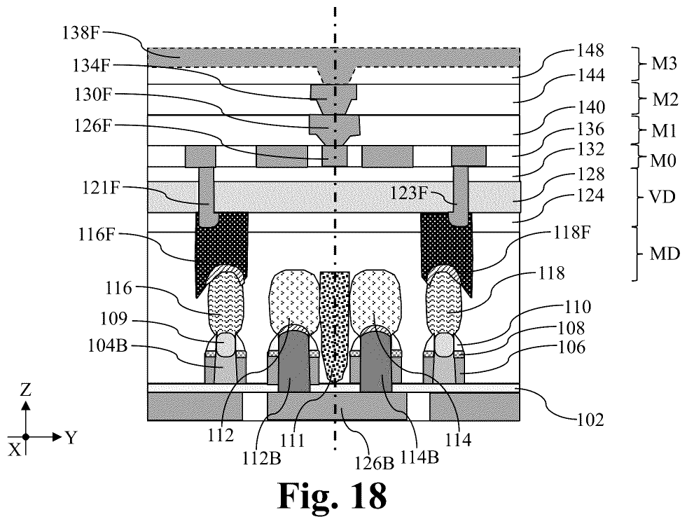

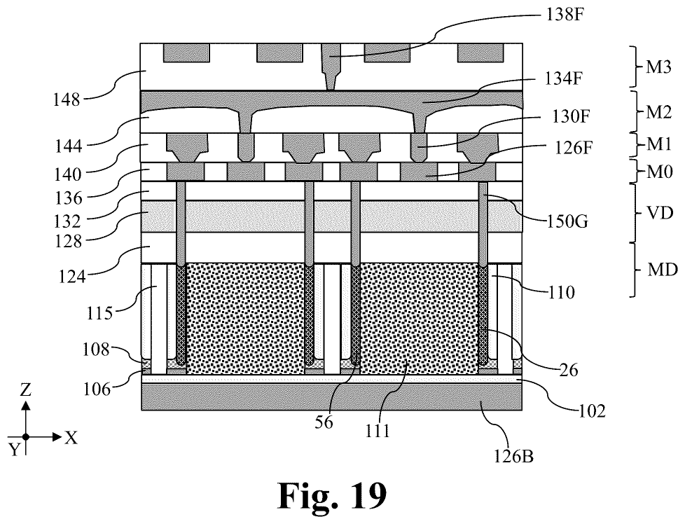

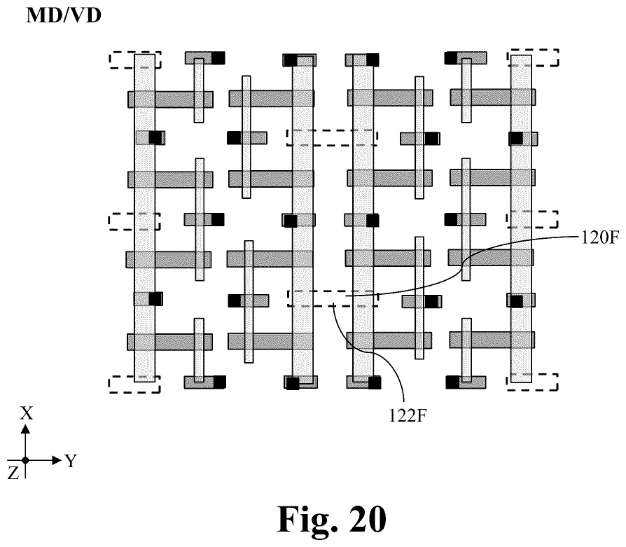

FIGS. 18-20 illustrate a second embodiment of the present disclosure. In the second embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 18-20, the common frontside source contact 120F and the frontside contact via 122F are omitted in the second embodiment. The M0 metal island 126F, the M1 metal island 130F, the M2 metal line 134F, and the M3 metal rail 138F are kept in place, even though they are no longer electrically coupled to the source features 112 and 114. Because the common frontside source contact 120F is not formed in the second embodiment, the isolation structure 111 is not etched and a portion of the isolation structure 111 extends between the source features 112 and 114 along the Y direction. While the M0 metal island 126F, the M1 metal island 130F, the M2 metal line 134F, and the M3 metal rail 138F do not serve any circuit function anymore, they may be kept simply because of the cost associated with fabricating new photolithography masks. Additionally, the M0 metal island 126F, the M1 metal island 130F, the M2 metal line 134F, and the M3 metal rail 138F may be kept because removing them may create process or loading variations.

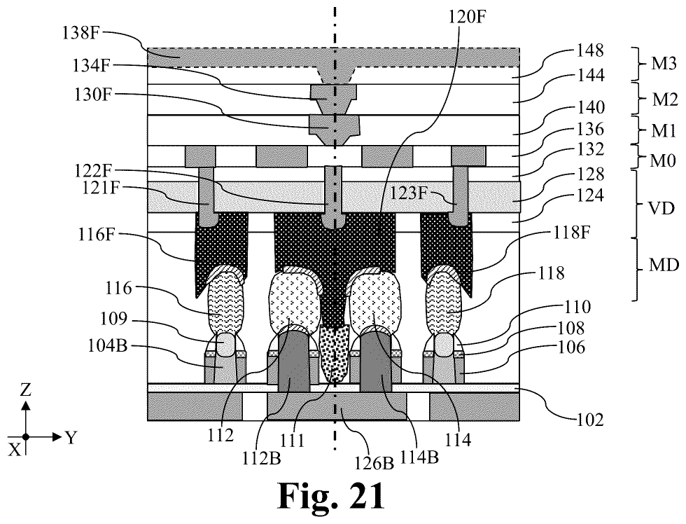

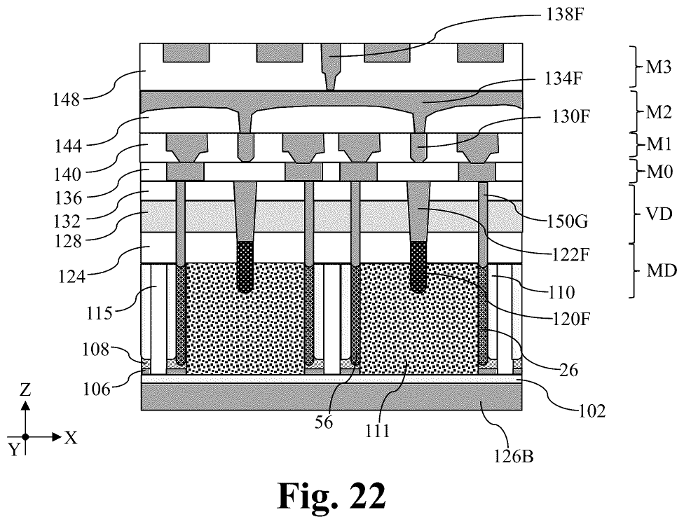

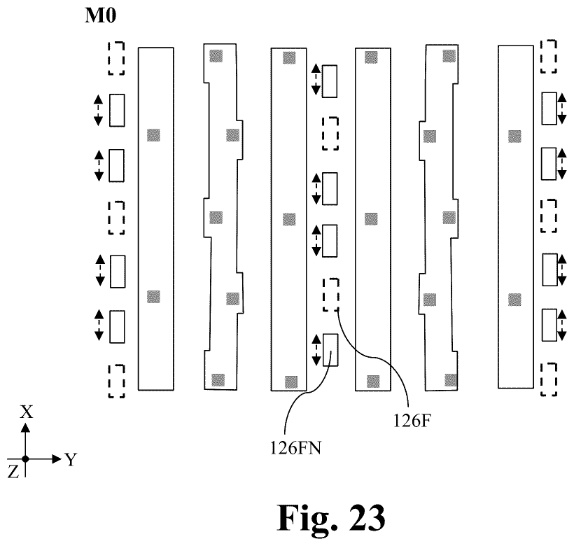

FIGS. 21-23 illustrate a third embodiment of the present disclosure. In the third embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 21-23, the M0 metal island 126F is omitted from the first metal layer M0. The omission of the M0 metal island 126F interrupts the electrical connection between the source features 112 and 114 and the M3 metal rail 138F. As shown in FIG. 23, when the M0 metal island 126F is omitted, the metal islands 126FN in the same first metal layer (M0) may be lengthened along the X direction to increase process window and via landing arca.

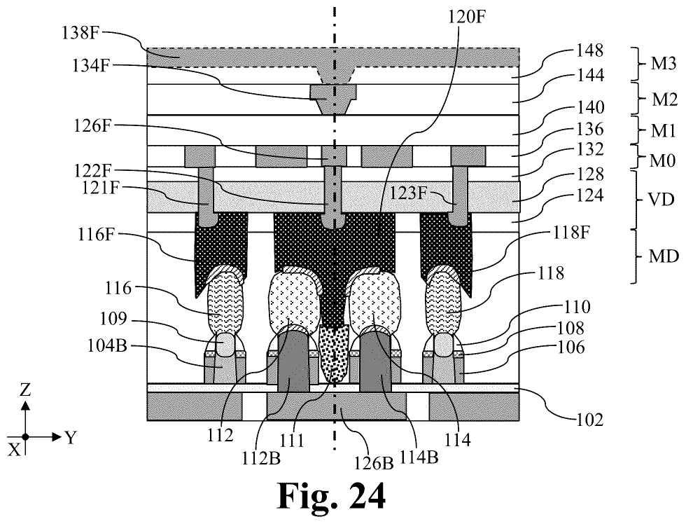

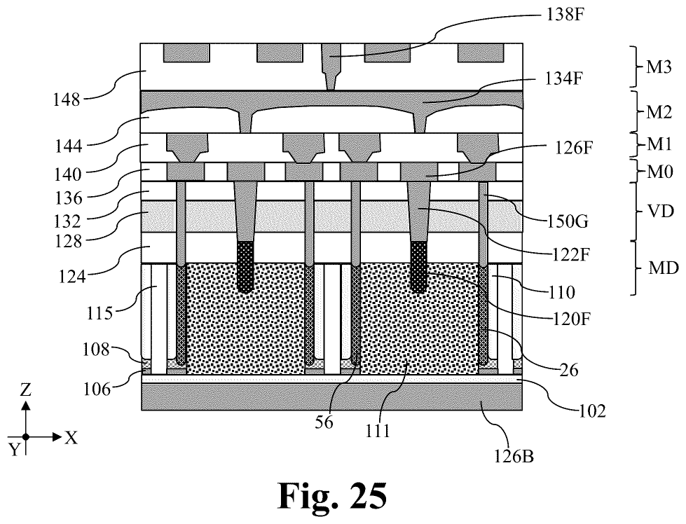

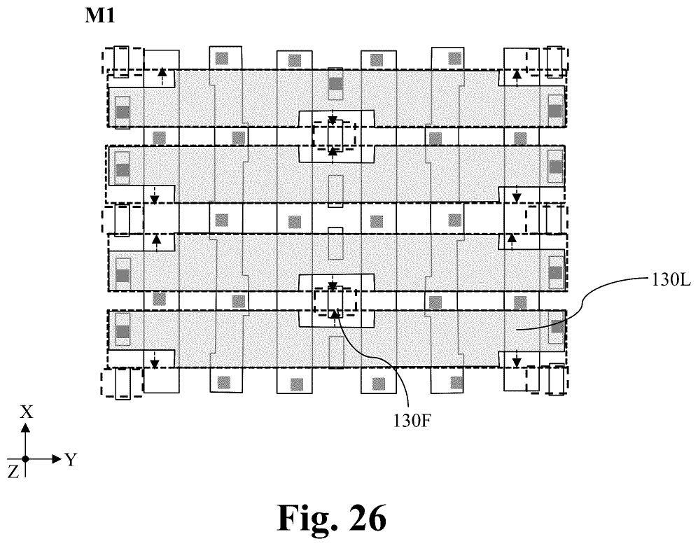

FIGS. 24-26 illustrate a fourth embodiment of the present disclosure. In the fourth embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 24-26, the M1 metal island 130F is omitted from the second metal layer M1. The omission of the M1 metal island 130F interrupts the electrical connection between the source features 112 and 114 and the M3 metal rail 138F. As shown in FIG. 26, when the M1 metal island 130F is omitted, the M1 metal line 130L may have a rectangular shape that is easier to form with greater process window.

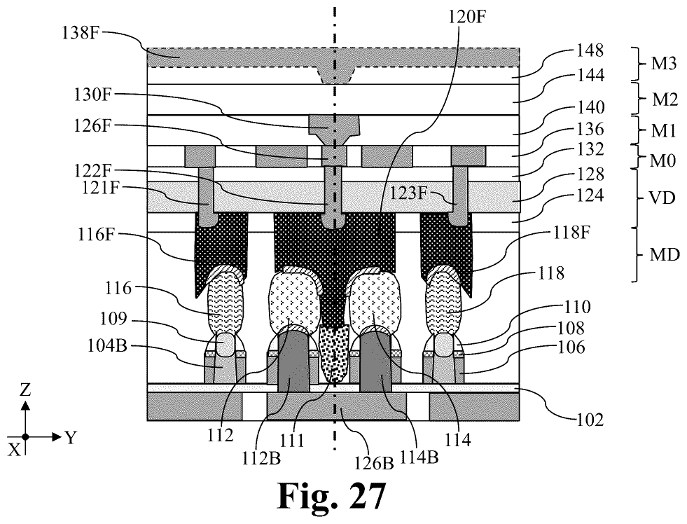

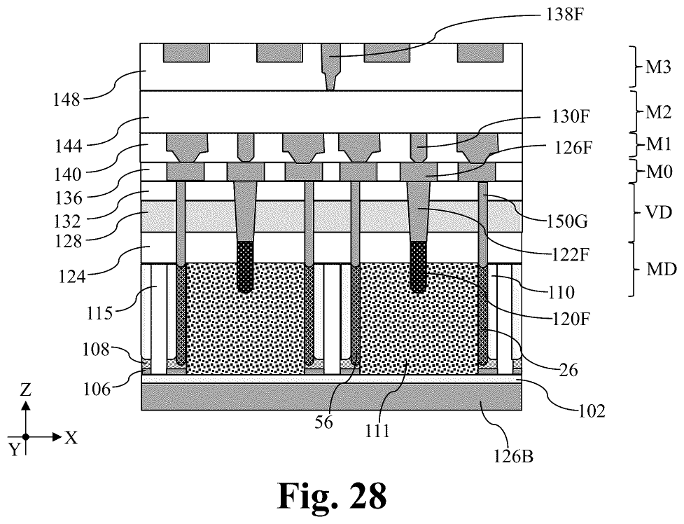

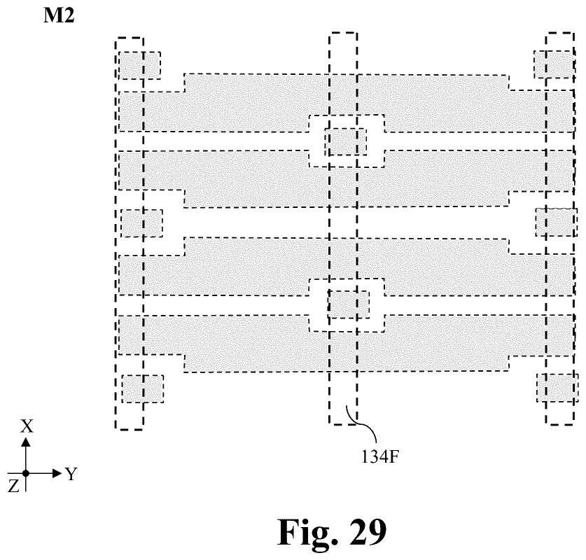

FIGS. 27-29 illustrate a fifth embodiment of the present disclosure. In the fifth embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 27-29, the M2 metal line 134F is omitted from the third metal layer M2. The omission of the M2 metal line 134F interrupts the electrical connection between the source features 112 and 114 and the M3 metal rail 138F. As shown in FIG. 29, when the M2 metal line 134F is omitted, the third metal layer M2 may be repurposed to accommodate other conductive features.

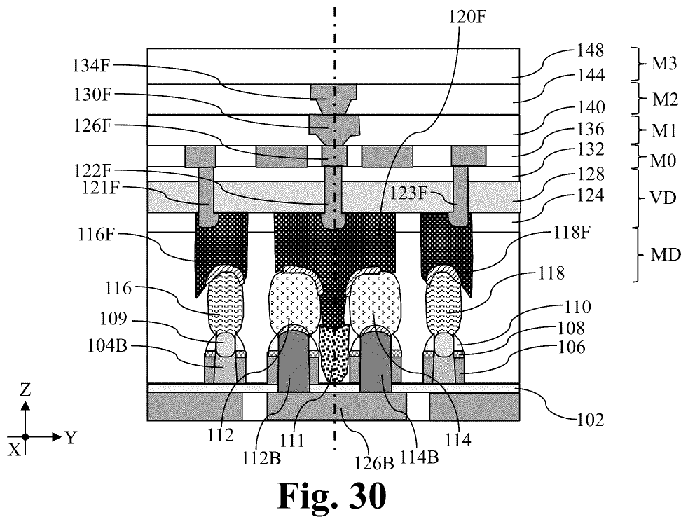

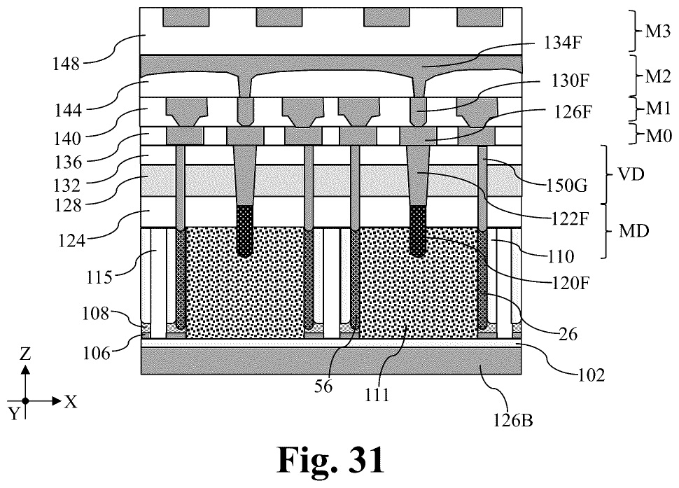

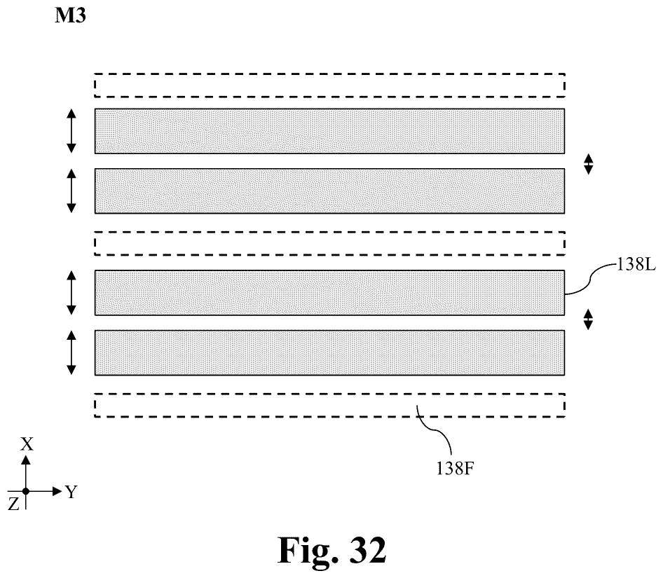

FIGS. 30-32 illustrate a sixth embodiment of the present disclosure. In the sixth embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 30-32, the M3 metal rail 138F is omitted from the fourth metal layer M3. That is, source features 112 and 114 no longer have a frontside power rail to connect to anymore. As shown in FIG. 32, when the M3 metal rail 138F is omitted, the M3 metal lines 138L may each have a greater width to reduce resistance or be spaced apart from one another at a larger spacing to reduce parasitic capacitance.

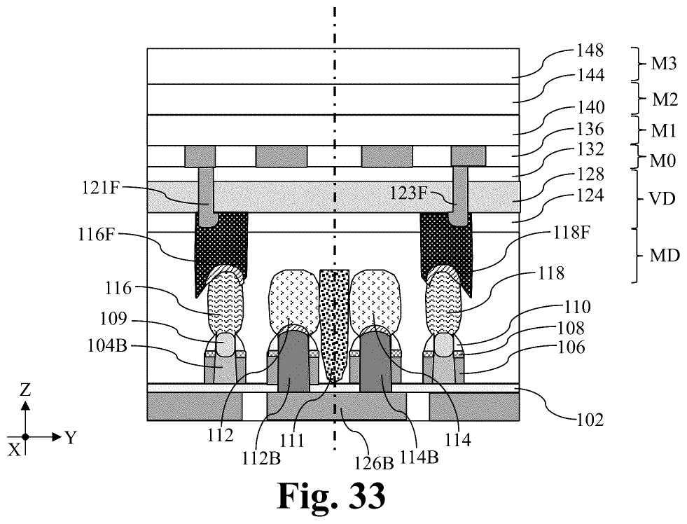

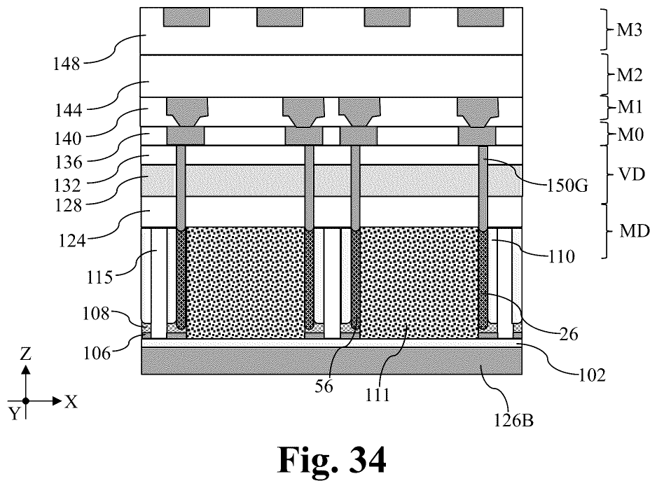

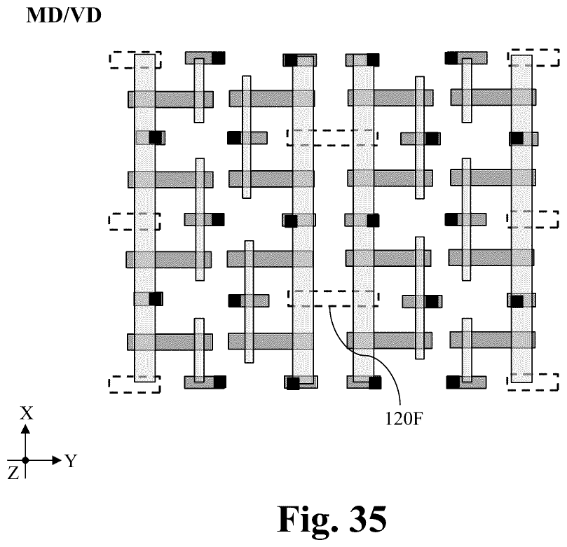

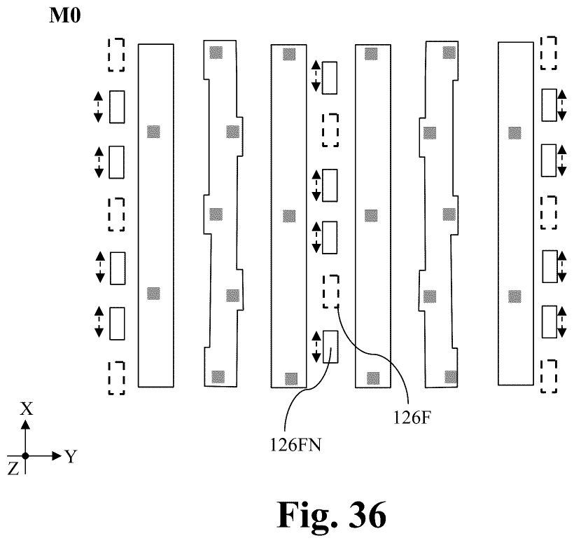

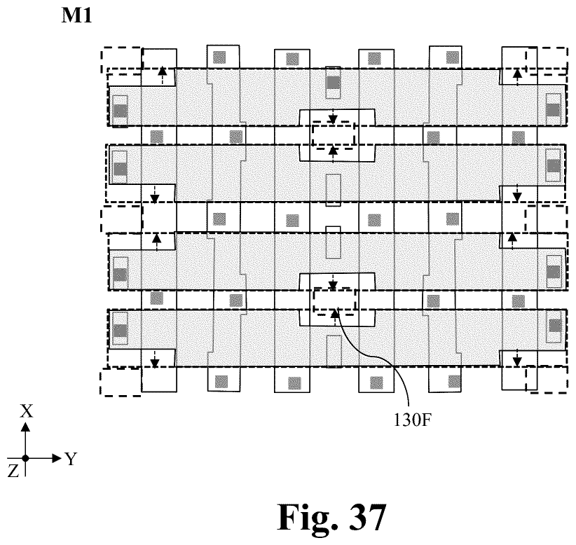

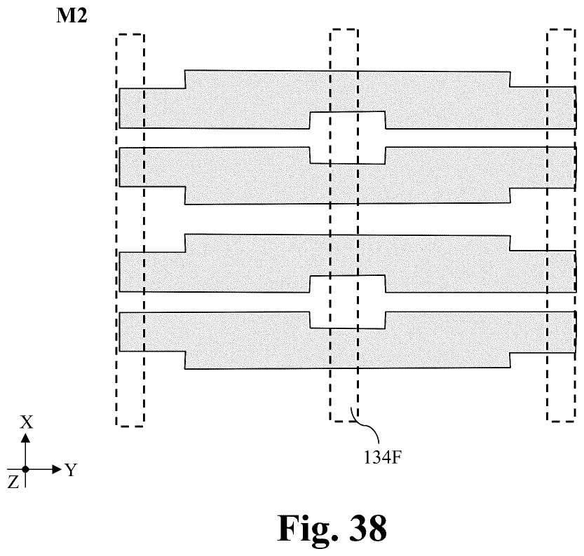

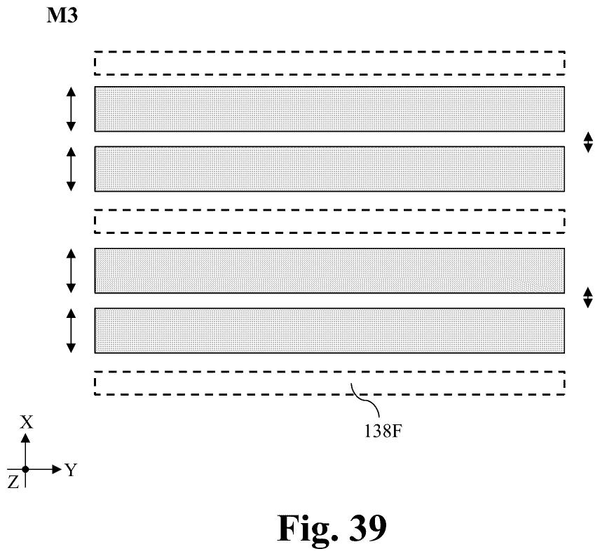

FIGS. 33-39 illustrate a seventh embodiment of the present disclosure. In the seventh embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. In the seventh embodiments, the common frontside source contact 120F, the frontside contact via 122F, the M0 metal island 126F, the M1 metal island 130F, the M2 metal line 134F, and the M3 metal rail 138F are all omitted. Because the common frontside source contact 120F is not formed in the second embodiment, the isolation structure 111 is not etched and a portion of the isolation structure 111 extends between the source features 112 and 114 along the Y direction. As shown in FIG. 36, when the M0 metal island 126F is omitted, the metal islands 126FN in the same metal layer may be lengthened along the X direction to increase process window and via landing area. As shown in FIG. 37, when the M1 metal island 130F is omitted, the M1 metal line 130L may have a rectangular shape that is easier to form with greater process window. As shown in FIG. 38, when the M2 metal line 134F is omitted, the third metal layer M2 may be repurposed to accommodate other conductive features. As shown in FIG. 39, when the M3 metal rail 138F is omitted, the M3 metal lines 138L may each have a greater width to reduce resistance or be spaced apart from one another at a larger spacing to reduce parasitic capacitance.

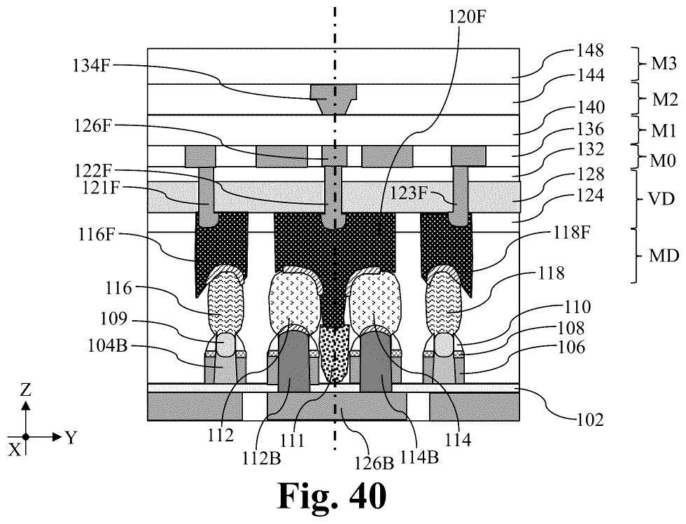

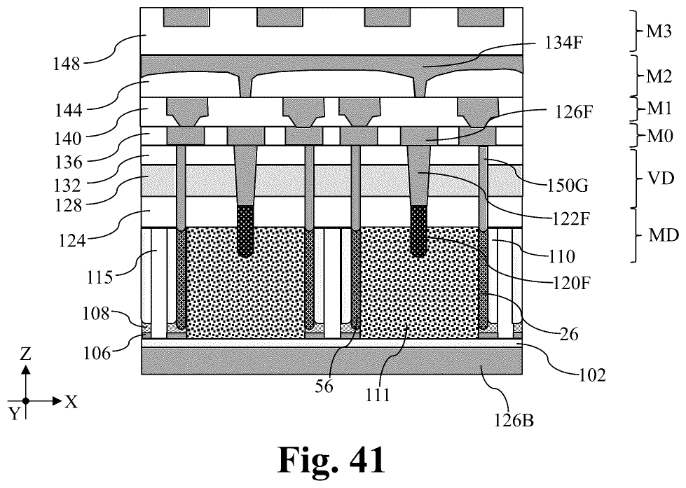

FIGS. 40-41 illustrate an eighth embodiment of the present disclosure. In the eighth embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 40 and 41, the M1 metal island 130F and the M3 metal rail 138F are omitted.

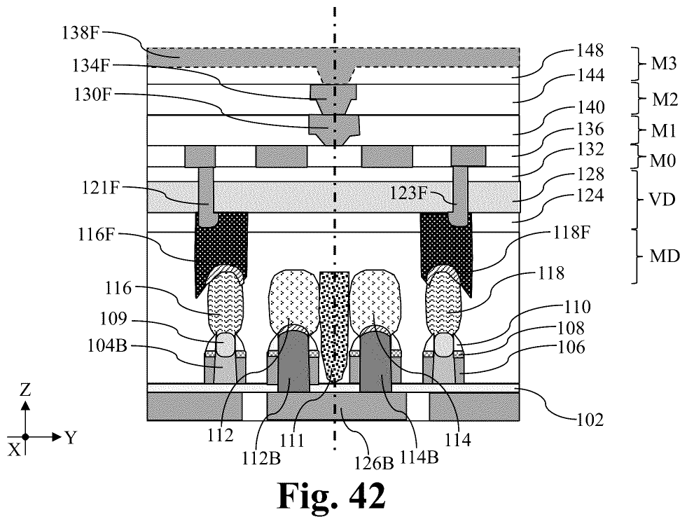

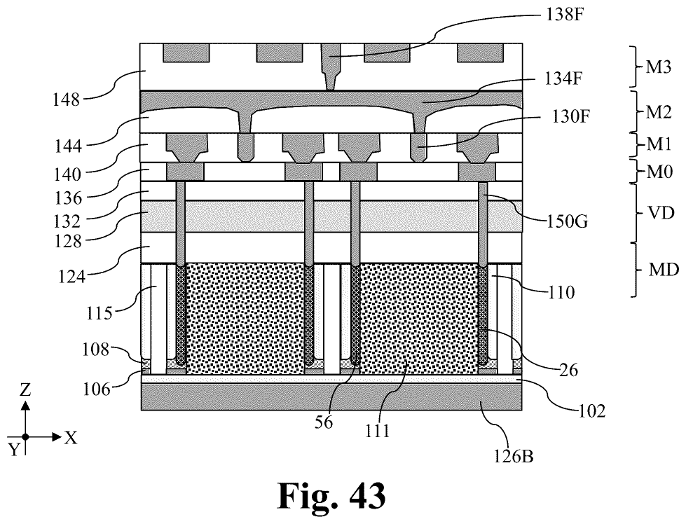

FIGS. 42-43 illustrate a ninth embodiment of the present disclosure. In the ninth embodiment, the source feature 112 of the second pull-down transistor PD2 of the SRAM cell 10 and the source feature 114 of the second pull-down transistor PD2 of a neighboring SRAM cell are coupled to the backside metal rail 126B by way of the first backside source contact 112B and the second backside source contact 114B. The isolation structure 111 is disposed between the first backside source contact 112B and the second backside source contact 114B along the Y direction. As shown in FIGS. 42 and 43, the common frontside source contact 120F, the frontside contact via 122F, and the M0 metal island 126F are omitted. Because the common frontside source contact 120F is not formed in the second embodiment, the isolation structure 111 is not etched and a portion of the isolation structure 111 extends between the source features 112 and 114 along the Y direction. While not explicitly shown in figures, omission of the M0 metal island 126F would allow similarly situated metal islands in the first metal layer (M0) to be lengthened along the X direction to increase process window and via landing area.

In one example aspect, the present disclosure provides a semiconductor structure. The semiconductor structure includes a backside metal line, a backside dielectric layer over the backside metal line, a first source/drain feature and a second source/drain feature over the backside dielectric layer, a first backside contact extending from the backside metal line, through the backside dielectric layer, to electrically couple to a bottom surface of the first source/drain feature, a second backside contact extending from the backside metal line, through the backside dielectric layer, to electrically couple to a bottom surface of the second source/drain feature, a dielectric layer disposed over the backside dielectric layer, the first source/drain feature and the second source/drain feature, a common contact extending through the dielectric layer to electrically couple to the first source/drain feature and the second source/drain feature, and an etch stop layer disposed over and interfacing the dielectric layer and the common contact. The common contact is not electrically coupled to any conductive feature that extends through the etch stop layer.

In some embodiments, a lower portion of the common contact extends between the first source/drain feature and the second source/drain feature. In some implementations, the semiconductor structure further includes an isolation structure dielectric fin disposed over the backside dielectric layer between the first backside contact and the second backside contact. The lower portion of the common contact lands on the isolation structure. In some instances, the semiconductor structure further includes at first base fin and a second base fin over the backside dielectric layer such that the first backside contact and the second backside contact are disposed between the first base fin and the second base fin, a third source/drain feature disposed over the first base fin, a fourth source/drain feature disposed over the second base fin. The first source/drain feature and the second source/drain feature are disposed between the third source/drain feature and the fourth source/drain feature. In some implementations, the first source/drain feature and the second source/drain feature include silicon and an n-type dopant and the third source/drain feature and the fourth source/drain feature include silicon germanium and a p-type dopant. In some embodiments, the semiconductor structure further includes a first bottom isolation layer disposed between a top surface of the first base fin and a bottom surface of the third source/drain feature, and a second bottom isolation layer disposed between a top surface of the second base fin and a bottom surface of the fourth source/drain feature. In some implementations, the first bottom isolation layer and the second bottom isolation layer include silicon nitride. In some embodiments, the semiconductor structure further includes a first source/drain contact extending through the dielectric layer to electrically couple to the third source/drain feature and a second source/drain contact extending through the dielectric layer to electrically couple to the fourth source/drain feature. The etch stop layer is disposed on top surfaces of the first source/drain contact and the second source/drain contact. In some embodiments, the semiconductor structure further includes a first contact via extending through the etch stop layer and partially extending into the first source/drain contact, and a second contact via extending through the etch stop layer and partially extending into the second source/drain contact.

Another aspect of the present disclosure pertains to a semiconductor structure. The semiconductor structure includes a backside metal line extending along a first direction, a backside dielectric layer over the backside metal line, a first gate structure and a second gate structure over the backside dielectric layer and extending lengthwise along a second direction perpendicular to the first direction, an isolation structure disposed over the backside dielectric layer and sandwiched between the first gate structure and the second gate structure along the first direction, a dielectric layer over and interfacing the isolation structure, a contact feature extending through the dielectric layer and partially extending into the isolation structure, an etch stop layer over and interfacing top surfaces of the dielectric layer and the contact feature. The contact feature is not electrically coupled to any conductive feature that extends through the etch stop layer.

In some embodiments, the semiconductor structure further includes a first gate contact extending through the etch stop layer and the dielectric layer to couple to the first gate structure, and a second gate contact extending through the etch stop layer and the dielectric layer to couple to the second gate structure. In some embodiments, the isolation structure includes silicon oxide. In some embodiments, top surfaces of the first gate structure, the gate cut feature, and the second gate structure are coplanar. In some implementations, the dielectric layer includes silicon oxide and the etch stop layer includes silicon nitride, silicon carbide, silicon carbonitride, aluminum oxide, or aluminum oxynitride. In some instances, the contact feature includes cobalt.

Yet another aspect of the present disclosure pertains to a semiconductor structure. The semiconductor structure includes a backside metal line, a backside dielectric layer over the backside metal line, a first n-type epitaxial feature and a second n-type epitaxial feature over the backside dielectric layer, a first backside contact extending from the backside metal line, through the backside dielectric layer, to electrically couple to a bottom surface of the first n-type epitaxial feature, a second backside contact extending from the backside metal line, through the backside dielectric layer, to electrically couple to a bottom surface of the second n-type epitaxial feature, a dielectric layer disposed over the backside dielectric layer, the first n-type epitaxial feature and the second n-type epitaxial feature, a common contact extending through the dielectric layer to electrically couple to the first n-type epitaxial feature and the second n-type epitaxial feature, and an etch stop layer disposed over and interfacing top surfaces of the dielectric layer and the common contact. The common contact is not electrically coupled to any conductive feature that extends through the etch stop layer and a lower portion of the common contact extends between the first n-type epitaxial feature and the second n-type epitaxial feature.

In some embodiments, the semiconductor structure further includes an isolation structure disposed over the backside dielectric layer between the first backside contact and the second backside contact. The lower portion of the common contact lands on the isolation structure. In some embodiments, the semiconductor structure further includes a first semiconductor fin and a second semiconductor fin over the backside dielectric layer such that the first backside contact and the second backside contact are disposed between the first semiconductor fin and the second semiconductor fin, a first p-type epitaxial feature disposed over the first semiconductor fin, and a second p-type epitaxial feature disposed over the second semiconductor fin. The first n-type epitaxial feature and the second n-type epitaxial feature are disposed between the first p-type epitaxial feature and the second p-type epitaxial feature. In some embodiments, the semiconductor structure further includes a first bottom isolation layer disposed between a top surface of the first semiconductor fin and a bottom surface of the first p-type epitaxial feature, and a second bottom isolation layer disposed between a top surface of the second semiconductor fin and a bottom surface of the second p-type epitaxial feature. In some instances, the first bottom isolation layer and the second bottom isolation layer include silicon nitride.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a backside metal line;
a backside dielectric layer over the backside metal line;
a first source/drain feature and a second source/drain feature over the backside dielectric layer;
a first backside contact extending from the backside metal line, through the backside dielectric layer, to electrically couple to a bottom surface of the first source/drain feature;
a second backside contact extending from the backside metal line, through the backside dielectric layer, to electrically couple to a bottom surface of the second source/drain feature;
a dielectric layer disposed over the backside dielectric layer, the first source/drain feature and the second source/drain feature;
a common contact extending through the dielectric layer to electrically couple to the first source/drain feature and the second source/drain feature; and
an etch stop layer disposed over and interfacing the dielectric layer and the common contact,
wherein the common contact is not electrically coupled to any conductive feature that extends through the etch stop layer.

2. The semiconductor structure of claim 1, wherein a lower portion of the common contact extends between the first source/drain feature and the second source/drain feature.

3. The semiconductor structure of claim 2, further comprising:
an isolation structure dielectric fin disposed over the backside dielectric layer between the first backside contact and the second backside contact,
wherein the lower portion of the common contact lands on the isolation structure.

4. The semiconductor structure of claim 1, further comprising:
at first base fin and a second base fin over the backside dielectric layer such that the first backside contact and the second backside contact are disposed between the first base fin and the second base fin;
a third source/drain feature disposed over the first base fin; and
a fourth source/drain feature disposed over the second base fin,
wherein the first source/drain feature and the second source/drain feature are disposed between the third source/drain feature and the fourth source/drain feature.

5. The semiconductor structure of claim 4,
wherein the first source/drain feature and the second source/drain feature comprise silicon and an n-type dopant,
wherein the third source/drain feature and the fourth source/drain feature comprise silicon germanium and a p-type dopant.

6. The semiconductor structure of claim 4, further comprising:
a first bottom isolation layer disposed between a top surface of the first base fin and a bottom surface of the third source/drain feature; and
a second bottom isolation layer disposed between a top surface of the second base fin and a bottom surface of the fourth source/drain feature.

7. The semiconductor structure of claim 6, wherein the first bottom isolation layer and the second bottom isolation layer comprise silicon nitride.

8. The semiconductor structure of claim 4, further comprising:
a first source/drain contact extending through the dielectric layer to electrically couple to the third source/drain feature; and
a second source/drain contact extending through the dielectric layer to electrically couple to the fourth source/drain feature,
wherein the etch stop layer is disposed on top surfaces of the first source/drain contact and the second source/drain contact.

9. The semiconductor structure of claim 8, further comprising:
a first contact via extending through the etch stop layer and partially extending into the first source/drain contact; and
a second contact via extending through the etch stop layer and partially extending into the second source/drain contact.

10. A semiconductor structure, comprising:
a backside metal line extending along a first direction;
a backside dielectric layer over the backside metal line;
a first gate structure and a second gate structure over the backside dielectric layer and extending lengthwise along a second direction perpendicular to the first direction;
an isolation structure disposed over the backside dielectric layer and sandwiched between the first gate structure and the second gate structure along the first direction;
a dielectric layer over and interfacing the isolation structure;
a contact feature extending through the dielectric layer and partially extending into the isolation structure;
an etch stop layer over and interfacing top surfaces of the dielectric layer and the contact feature;
wherein the contact feature is not electrically coupled to any conductive feature that extends through the etch stop layer.

11. The semiconductor structure of claim 10, further comprising:
a first gate contact extending through the etch stop layer and the dielectric layer to couple to the first gate structure; and
a second gate contact extending through the etch stop layer and the dielectric layer to couple to the second gate structure.

12. The semiconductor structure of claim 10, wherein the isolation structure comprises silicon oxide.

13. The semiconductor structure of claim 10, wherein top surfaces of the first gate structure, the gate cut feature, and the second gate structure are coplanar.

14. The semiconductor structure of claim 10,
wherein the dielectric layer comprises silicon oxide,
wherein the etch stop layer comprises silicon nitride, silicon carbide, silicon carbonitride, aluminum oxide, or aluminum oxynitride.

15. The semiconductor structure of claim 10, wherein the contact feature comprises cobalt.

16. A semiconductor structure, comprising:
a backside metal line;
a backside dielectric layer over the backside metal line;
a first n-type epitaxial feature and a second n-type epitaxial feature over the backside dielectric layer;
a first backside contact extending from the backside metal line, through the backside dielectric layer, to electrically couple to a bottom surface of the first n-type epitaxial feature;
a second backside contact extending from the backside metal line, through the backside dielectric layer, to electrically couple to a bottom surface of the second n-type epitaxial feature;
a dielectric layer disposed over the backside dielectric layer, the first n-type epitaxial feature and the second n-type epitaxial feature;
a common contact extending through the dielectric layer to electrically couple to the first n-type epitaxial feature and the second n-type epitaxial feature; and
an etch stop layer disposed over and interfacing top surfaces of the dielectric layer and the common contact,
wherein the common contact is not electrically coupled to any conductive feature that extends through the etch stop layer,
wherein a lower portion of the common contact extends between the first n-type epitaxial feature and the second n-type epitaxial feature.

17. The semiconductor structure of claim 16, further comprising:
an isolation structure disposed over the backside dielectric layer between the first backside contact and the second backside contact,
wherein the lower portion of the common contact lands on the isolation structure.

18. The semiconductor structure of claim 16, further comprising:
a first semiconductor fin and a second semiconductor fin over the backside dielectric layer such that the first backside contact and the second backside contact are disposed between the first semiconductor fin and the second semiconductor fin;
a first p-type epitaxial feature disposed over the first semiconductor fin; and
a second p-type epitaxial feature disposed over the second semiconductor fin,
wherein the first n-type epitaxial feature and the second n-type epitaxial feature are disposed between the first p-type epitaxial feature and the second p-type epitaxial feature.

19. The semiconductor structure of claim 18, further comprising:
a first bottom isolation layer disposed between a top surface of the first semiconductor fin and a bottom surface of the first p-type epitaxial feature; and
a second bottom isolation layer disposed between a top surface of the second semiconductor fin and a bottom surface of the second p-type epitaxial feature.

20. The semiconductor structure of claim 19, wherein the first bottom isolation layer and the second bottom isolation layer comprise silicon nitride.
